(19) United States
(12) Patent Application Publication
(10) Pub. No.: US 2008/0224327 A1
(43) Pub. Date: Sep. 18, 2008

(54) Microelectronic substrate including bumping sites with nanostructures

(76) Inventors: Daewoong Suh, Phoenix, AZ (US); Nachiket Raravikar, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/717,239

(22) Filed: Mar. 13, 2007

(51) Int. Cl. H01L 23/48

(52) U.S. Cl. 257/782

(57) ABSTRACT

A microelectronic substrate and a package including the substrate. The substrate comprises: a wafer; circuitry disposed within the wafer and including a plurality of bonding pads; and a plurality of bumping sites disposed on respective ones of the bonding pads, each of the bumping sites comprising a nanolayer including columnar nanostructures.

### FIELD

Embodiments of the present invention relate generally to the field of microelectronic fabrication. In particular, embodiments relate to surface finish structures and methods of providing surface finishes on microelectronic substrates.

### BACKGROUND

Flip-chip attach processes typically involve a reflow of solder bumps to form solder joints between a die and substrate. The substrate usually includes substrate bumping sites thereon, and the die includes die bumping sites thereon adapted to be joined to the substrate bumping sites to establish an electrical connection between the die and the substrate. The substrate and/or die bumping sites may include under bump metallization surface finishes including a copper layer on the die/substrate bonding pads, a nickel layer on the copper layer, and a gold layer, a silver layer (known as “immersion silver”), or a layer of palladium on the nickel layer. Noble metals such as gold, silver or palladium are usually provided for their inertness to attack by corrosive substances, i.e., for their resistance to oxidation, and to improve wettability of the molten solder. Solder bumps are provided onto bumping sites of the substrate and/or die. However, oxidation prevention by providing a gold layer can be expensive.

In order to address the above, more cost-effective coatings such as tin or organic coatings, such as OSP (Organic Solderability Protection) on copper, for example, have been provided. However, the above coatings present problems, in that the effectiveness of OSP to protect underlying wettable surfaces against oxidation degrades gradually with time. As a result, OSP coated surfaces have limited storage life and are therefore not widely used.

The prior art fails to provide a cost-effective surface finish structure for a substrate to allow a reliable and efficient flip-chip mounting of a die to the substrate.

### BRIEF DESCRIPTION OF THE DRAWINGS

FIG. 1 is a schematic cross-sectional view of a package according to an embodiment;

FIG. 2a is a schematic view of an arrangement to provide nanostructures in the form of carbon nano-tubes by way of electrophoresis;

FIG. 2b is a schematic, enlarged view of the negative electrode and/or substrate in the arrangement of FIG. 2a;

FIG. 3 is a schematic view of an arrangement to provide nanostructures in the form of nano-wires or nano-springs using glancing angle deposition (GLAD); and

FIG. 4 is a schematic view of an embodiment of a system incorporating a microelectronic package as shown in FIG. 1.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic substrate and a package including the substrate are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent to a second element may be directly in contact with the second element or it may include one or more intervening elements. In addition, in the instant description, figures and/or elements may be referred to in the alternative. In such a case, for example where the description refers to FIGS. X/Y showing an element A/B, what is meant is that FIG. X shows element A and FIG. Y shows element B. In addition, a “layer” as used herein may refer to a layer made of a single material, a layer made of a mixture of different components, a layer made of various sub-layers, each sub-layer also having the same definition of layer as set forth above.

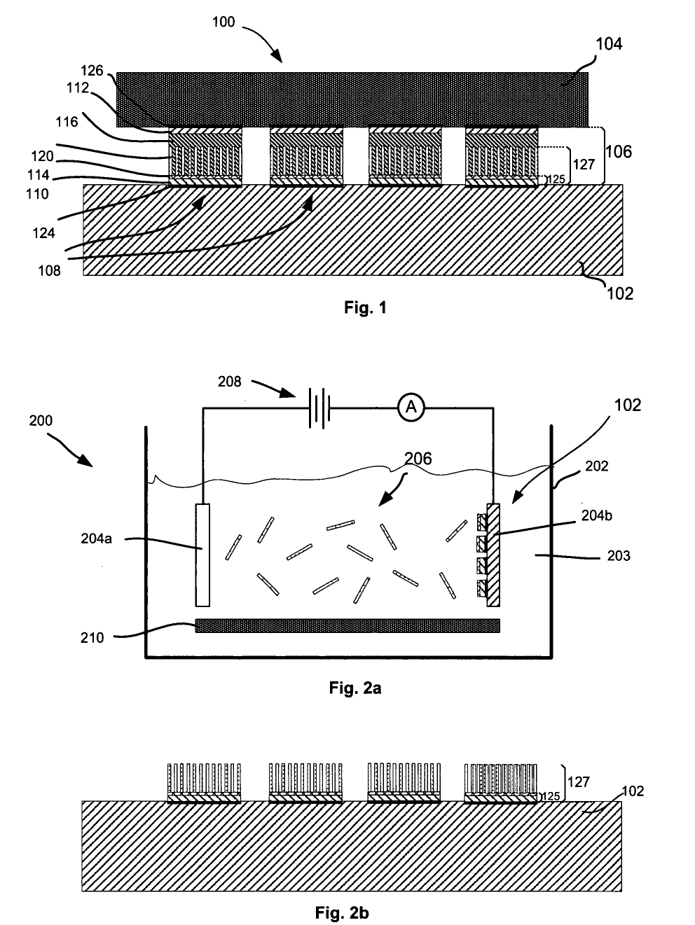

Aspects of this and other embodiments will be discussed herein with respect to FIGS. 1-4 below. The figures, however, should not be taken to be limiting, as it is intended for the purpose of explanation and understanding.

Referring first to FIG. 1, a microelectronic package 100 is shown according to an embodiment. Package 104 includes a substrate 102, and a die 104 bonded to the substrate by a bond 106. By “bond,” what is meant in the context of embodiments is at least an electrical joint between the die and the substrate. The bond may further include a mechanical joint between the die and the substrate. As seen in FIG. 1, a plurality of joint structures 108 are shown between the die 104 and the substrate 102, the joint structures 108 forming at least part of bond 106. Optionally, the bond 106 may also include an underfill material (not shown) provided in a well known manner.

Referring still to FIG. 1, the joint structures 108 include a bonding pad 124 and 126 of the substrate and die, respectively. By “bonding pad,” what is meant in the context of the present description is the portion of the conductive pattern on printed circuits on either the die or the substrate designed to allow an electrical bonding of the die or substrate to external circuitry. Joint structures may further include an electrically conductive layer 110 on the bonding pads 124 of the substrate, and an electrically conductive layer 112 on the bonding pads 126 of the die. Each of electrically conductive layers 110 and 112 may include, for example, a copper layer directly in contact with the bonding pads 124 and 126, respectively, although layers 110 and 112 may include any suitable electrically conductively material, such as, for example, aluminum or silver. Preferably, as seen in FIG. 1, a barrier layer 114, such as, for example, a layer comprising nickel, may be provided on the electrically conductive layer 110 adjacent the substrate, or even on the electrically conductive layer 112 adjacent to the die (not shown). By “barrier layer,” what is meant in the context of the present description is a layer adapted to prevent migration of electrically conductive material as recognized by one skilled in the art.

As further shown in FIG. 1, joint structures 108 comprise solidified solder 116 bonding the die 10* and the substrate 102 to one another in a well known manner. Joint structures 108 further comprise a nano-layer 118 including columnar nanostructures 120. According to a preferred embodiment, as shown in FIG. 1, the columnar nanostructures are vertically aligned, that is, they all extend perpendicularly with respect to active surface 122 of the substrate. Preferably, the nanostructures 120 include at least one of carbon-nano tubes, nano-wires and nano-springs. Where carbon nano-tubes are provided, they may include one of single wall carbon nano-tubes (SWCNT) or multi-wall carbon nano-tubes (MWCNT). Where the nanostructures comprise either nano-wires or nano-springs, they may comprise at least one of copper, cobalt, nickel and tungsten. Preferably, the nanostructures have an inter-columnar distance or Van der Waals gap between about 0.34 nm and about 1 micron, a height between about 100 nm and about 1 micron, and a width or diameter between about 1 nm and about 100 nm.

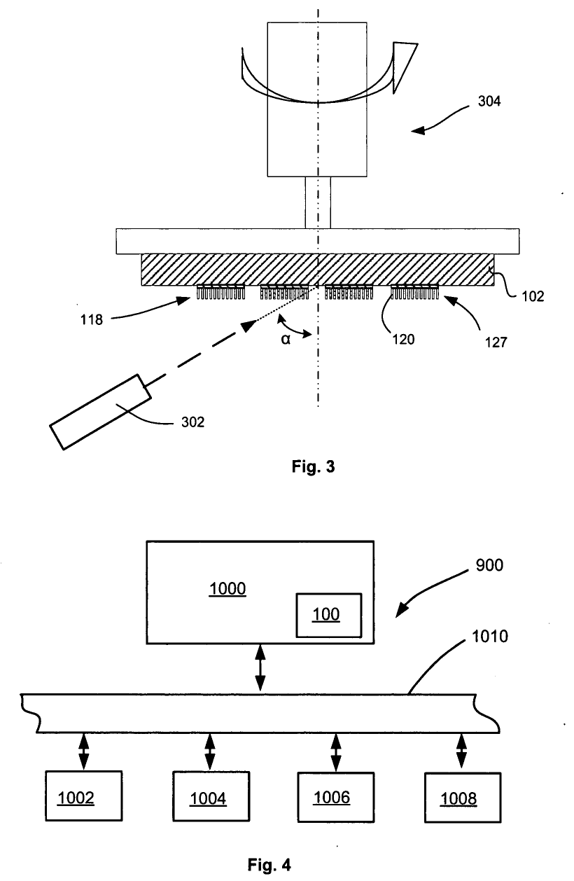

FIGS. 2a and 3 depict two embodiments for providing bumping sites having nanostructures on bonding pads of a substrate such as substrate 102 of FIG. 1. While FIG. 2a shows an arrangement to provide nanostructures in the form of carbon nano-tubes by way of electrophoresis, FIG. 3 shows an arrangement to provide nanostructures in the form of nano-wires or nano-springs using glancing angle deposition (GLAD). It is noted that, for the remainder of the instant description, the totality of the layers on the bonding pads 124 of substrate 102 onto which the columnar nanostructures 120 are to be provided will hereinafter be referred to as the “surface finish” 125 of the substrate. Although FIG. 1 merely shows an electrically conductive layer 110 and a barrier layer 114 as making up the surface finish 125 of the substrate, embodiments are not so limited, and include within their scope any known surface finish as would be recognized by one skilled in the art. In addition, in the instant description, the sum of the surface finish and the columnar nanostructures is referred to herein as the “bumping site” 127 of the substrate.

Referring first to FIG. 2a, a carbon nanotube (CNT) arrangement 200 is shown which is adapted to provide carbon nanotubes such as nanotubes 120 on the surface finishes, such as surfaces finishes 125, of a substrate by way of DC electrophoresis according to a first embodiment. The arrangement shown in FIG. 2a may include a conventional CNT electrophoresis arrangement except for the fact that the electrophoresis target includes surfaces finishes of a microelectronic substrate. In the shown arrangement, nanotubes move towards a negative electrode and align along the electric field. Arrangement 200 includes an electrophoresis bath 202 in which a CNT powder suspension 203 including carbon nanotubes 206 is suspended in water, which may be distilled or non-distilled. Preferably, powder suspension 203 further includes Mg(NO₃)₂6H₂O. More preferably, the Mg(NO₃)₂6H₂O is provided at between about 10⁻⁶ and 10⁻² mole in order to get a surface charge, such as a positive charge, on the suspended CNT powder. The CNT powder including the carbon nanotubes 206 may include, for example SWNT's obtained by a conventional graphite electric arc method in a helium atmosphere. Alternatively, the nanotubes 206 may include MWNT's obtained by a conventional dc arc discharge method. For example, where SWNT's are used, raw material including about 60% by weight of SWNT's may be stirred for example in concentric nitric/sulfuric acid solution in various volume ratios. The SWNT acid suspension may be refluxed with magnetic stirring at about 80 degrees Celsius. The suspension may then be filtered on polytetrafluoroethylene filter paper. The filtered wet powder may be washed with distilled water. Referring still to FIG. 2a, the arrangement 200 further includes a pair of electrodes 204a and 204b disposed within the electrophoresis chamber 202 as shown, and a voltage source 208 applying an electric field across the electrodes, the negative electrode 204b being the substrate itself in the process of being provided with CNT's. Positive electrode 204a may include a mesh electrode to increase surface area and filter away any impurities, although embodiments contemplate the use of a positive electrode 204a which is a not a mesh electrode. As clearly seen in FIG. 2a, the CNT suspension 203 is disposed in the electric field applied across electrodes 204a and 204b by a voltage source 208, as a result of which the nanotubes 206 within suspension 203 are imparted with a positive surface charge. Element A in the circuit of FIG. 2a may include an ammeter or voltmeter to measure current in a conventional manner. Arrangement 200 may further include a magnetic agitator (not shown) disposed within electrophoresis chamber 202, the agitator being adapted to agitate the suspension 203 in a well known manner to prevent nanotubes from getting agglomerated by constantly stirring the solution. However, where, such as in the shown embodiment, it is contemplated that the nanotubes be positioned on the substrate in an aligned fashion, embodiments contemplate doing away with using an agitator in order to prevent disturbing such alignment. As a result of the nanotubes 206 in the suspension being positively charged in the electric field between the electrodes 204a and 204b, and of the surfaces finishes 125 being negatively charged, the nanotubes 206 move towards the negative electrode 204b, which in this case, includes the substrate 102 toward surface finishes 125, and align along the electric field, which, in the shown case, is oriented perpendicularly with respect to an active surface of the substrate. The resulting structure as shown in FIG. 2b, which shows the substrate 102 after deposition, includes bumping sites 127 comprising surface finishes 125 and a layer 118 of columnar nanostructures 120 formed thereon, the columnar nanostructures including carbon nanotubes.

Referring first to FIG. 3, GLAD arrangement 300 is shown which is adapted to provide nanostructures on the surface finishes, such as surfaces finishes 125 of substrate 102 according to a second embodiment. The arrangement shown in FIG. 2a may include a conventional GLAD arrangement except for the fact that the GLAD target includes surface finishes of a microelectronic substrate. FIG. 3 thus schematically shows a GLAD arrangement where a source 302 deposits nanostructures 120 in the form of nano-wires or nano-springs onto the surface finish 125 of substrate 102. Substrate 102 is shown as having been mounted to a chuck 304 which may be rotatable and/or translatable according to application needs. The flux angle a will affect the formation angle θ of the nanostructures 120 (the formation angle corresponding to the orientation angle of each of the nanostructures with respect to a line perpendicular to the active surface of each surface finish). The GLAD arrangement shown may use a regime of glancing or highly oblique angle deposition, typically at angles greater than about 75 degrees. Preferably, according to an embodiment, the flux angle a is chosen such that the formation angle θ is substantially equal to zero. Rotation and other movements of the substrate 102 would make nano-springs or nano-wires having desired shapes as would be recognized by one skilled in the art. Preferably, according to an embodiment, GLAD deposition takes place at room temperature in an inert atmosphere at least in part to avoid any possible oxidation of the nano-springs or nano-wires. Depending upon the flux angle a and on the speed of rotation of the substrate, if nano-springs are deposited, a pitch of the nano-springs would change, as would be recognized by one skilled in the art. The resulting structure includes bumping sites 127 comprising surface finishes 125 and a layer 118 of columnar nanostructures 120 formed thereon, the columnar nanostructures including nano-wires or nano-springs.

Advantageously, embodiments provide bumping sites where either carbon nano-tube or metallic nanostructures cover the surface finishes of a substrate onto which solder is to be reflowed to bond a die to the substrate. To the extent that nanostructures have extraordinarily high surface area, they thus increase the available wettable surface area of the surface finishes of the substrate. Nanomaterials are advantageously wettable by solders. In this way, when solder paste is dispensed onto the bumping sites of a substrate configured according to embodiments, there will be a significantly increased amount of wettable surface area available to the solder for wetting. Because of this increased surface area, the wetting angle of the solder according to embodiments is significantly reduced, and therefore, wetting is considerably increased. As a result, advantageously, embodiments obviate the need for expensive noble metal coatings provided in the prior art to prevent oxidation and to promote wetting. In addition, embodiments further enable flux-less soldering. In principle, if one continues to reduce contact angle (or increase wetting), then one eventually reaches the point where one does not need flux to enhance wetting. The main function of flux is to remove a very thin layer of a top surface of a metal and therefore expose a virgin (i.e. oxide-free) metallic surface. As a result, the total surface energy of virgin metal will be increased over oxide-covered metal because the surface energy per area of virgin metal is much higher than that of oxide-covered metal. Embodiments achieve the same results (i.e., higher total surface energy) by dramatically increasing the surface area as opposed to increasing surface energy per unit area. Thus, advantageously, embodiments do not necessarily require the use of flux, especially in the case of CNT's. Additionally, advantageously, to the extent that embodiments do not require the high activity of cleanable flux, optionally, they would render possible the use of no-clean fluxes

Regarding the advantage of increased wettability provided by increased surface area, it is noted that carbon nanotubes or metallic nanostructure (such as nano-wire, nano-rod, etc) has very high aspect ratio and therefore a very high surface-to-volume ratio. The equation shown below illustrates that by depositing vertically-aligned Single Wall CNT (SWCNT) or Multi Wall CNT (MWCNT), the effective surface area can be increased by a factor of 4000 to 28000. This surface area is a function of the nanotube aspect ratio and the inter-nanotube distance. Thus, where d represents the diameter of a nanotube, and l its length, then, the available surface area for wetting of the nanotube is given by the equation: exposed area=(πd²/4)+(πdl). The surface area (in cm²) of aligned MWNT arrays grown on a 1 cm×1 cm substrate is a function of inter-nanotube distance (which is a function of the nanotube array density) and the length of the nanotubes. The surface area is higher with larger nanotube lengths, and with smaller inter-nanotube distance (i.e. a higher nanotube array density). The above suggests that the provision of a layer of columnar nanostructures onto surface finishes of a substrate greatly increases the exposed wettable area for solder reflow.

Embodiments advantageously take advantage of the fact that wetting angle on rough surface areas can be reduced as compared to flat surfaces. The wetting angle (θ_{W}) on a rough surface is related to the wetting angle (θ_{E}) on flat surface according to cos θ_{W}=r cos θ_{E} where r is the ratio of the effective surface area of the rough surface to its projected area on a flat surface. This equation suggests that when θ_{E} is less than 90 degrees (in case of solder wetting), the contact angle decreases (i.e., wetting improves) as r increases (i.e., surface area of the rough surface increases). The huge increase of r by nano-material coating therefore effectively leads to substantially complete wetting (θ_{W}=0).

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package comprising:
a substrate;
a die bonded to the substrate;
a plurality of joint structures electrically bonding the die to the substrate, at least one of the plurality of joint structures comprising a nanolayer including columnar nanostructures.

2. The package of claim 1, wherein the nanostructures are vertically aligned.

3. The package of claim 1, wherein the nanostructures comprise at least one of carbon nano-tubes, nano-wires and nano-springs.

4. The package of claim 1, wherein the joints structures further comprise solidified solder.

5. The package of claim 2, wherein the at least one of nano-tubes and nano-wires comprise one of copper, cobalt, nickel and tungsten.

6. The package of claim 1, wherein the nanostructures have an inter-columnar distance gap between about 0.34 nm and about 1 micron, a height between about 100 nm and about 1 micron, and a width or diameter between about 1 nm and about 100 nm.

7. A microelectronic substrate comprising:
a wafer;
circuitry disposed within the wafer and including a plurality of bonding pads;
a plurality of bumping sites disposed on respective ones of the bonding pads, each of the bumping sites comprising a nanolayer including columnar nanostructures.

8. The substrate of claim 7, wherein the nanostructures are vertically aligned.

9. The substrate of claim 7, wherein the nanostructures comprise at least one of carbon nano-tubes, nano-wires and nano-springs.

10. The substrate of claim 7, wherein the joints structures further comprise solidified solder.

11. The substrate of claim 9, wherein the at least one of nano-tubes and nano-wires comprise one of copper, cobalt, nickel and tungsten.

12. The substrate of claim 7, wherein the nanostructures have an inter-columnar distance between about 0.34 nm and about 1 micron, a height between about 100 nm and about 1 micron, and a width or diameter between about 1 nm and about 100 nm.

13. A method of providing bumping sites on a microelectronic substrate comprising:
providing the substrate, the substrate including a plurality of bonding pads thereon;
providing a plurality of bumping sites disposed on respective ones of the bonding pads, each of the bumping sites comprising a nanolayer including columnar nanostructures.

14. The method of claim 13, wherein the nanostructures are vertically aligned.

15. The method of claim 13, wherein the nanostructures comprise at least one of carbon nano-tubes, nano-wires and nano-springs.
